(19) United States
(12) Patent Application Publication
(10) Pub. No.: US 2025/0331237 A1
(43) Pub. Date: Oct. 23, 2025

(54) SEMICONDUCTOR DEVICE INCLUDING A MULTI-BRIDGE CHANNEL FIELD-EFFECT TRANSISTOR

(71) Applicant: SAMSUNG ELECTRONICS CO., LTD., Suwon-si (KR)

(72) Inventors: Ki Hwan KIM, Suwon-si (KR); Sang Koo KANG, Suwon-si (KR); Gwi Rim PARK, Suwon-si (KR); Yeon Do JUNG, Suwon-si (KR); Pan Kwi PARK, Suwon-si (KR); Dong Suk SHIN, Suwon-si (KR)

(73) Assignee: SAMSUNG ELECTRONICS CO., LTD., Suwon-si (KR)

(21) Appl. No.: 18/958,499

(22) Filed: Nov. 25, 2024

(30) Foreign Application Priority Data
Apr. 22, 2024 (KR) 10-2024-0053623

(51) Int. Cl. H10D 30/67; H10D 30/01; H10D 30/43; H10D 62/10; H10D 62/13; H10D 64/01; H10D 64/27

(52) U.S. Cl. CPC H10D 30/6757; H10D 30/014; H10D 30/43; H10D 30/6735; H10D 62/121; H10D 62/151; H10D 64/021; H10D 64/513

(57) ABSTRACT

A semiconductor device includes a substrate, an active pattern on the substrate and extending in a first horizontal direction, at least one first nanosheet stacked on the active pattern and spaced apart from one another in a vertical direction, at least one second nanosheet stacked on the active pattern and spaced apart from one another in the vertical direction, a trench formed on the active pattern between the first and second nanosheets, a lower spacer disposed along a bottom surface of the trench, a source/drain region on the lower spacer within the trench, and a void formed within the trench between the lower spacer and the source/drain region. An uppermost surface of the lower spacer is formed lower than an uppermost surface of the active pattern. An uppermost surface of the void is formed higher than the uppermost surface of the active pattern.

### CROSS-REFERENCE TO RELATED APPLICATION

This application claims benefit of priority under 35 U.S.C. § 119 to Korean Patent Application No. 10-2024-0053623, filed on Apr. 22, 2024, in the Korean Intellectual Property Office, the disclosure of which is incorporated by reference in its entirety.

### BACKGROUND

### 1. Field

The present disclosure relates generally to a semiconductor device, and more particularly, to a semiconductor device including a multi-bridge channel field-effect transistor (MBCFET™).

### 2. Description of Related Art

A multi-gate transistor may have been proposed as a scaling technique for increasing the density of integrated circuit devices. A multi-gate transistor may refer to a transistor in which a silicon body in the form of a fin and/or nanowire may be formed on a substrate and a gate may be formed on the surface of the silicon body.

As such, the multi-gate transistor may take advantage of its three-dimensional (3D) channel, and thereby allowing for easy scaling in a vertical direction (e.g., up and/or down). Additionally, the multi-gate transistor may offer improved control over the current flowing through the transistor without a need to increase the gate length, when compared to related transistors. Furthermore, the multi-gate transistor may mitigate and/or reduce a short channel effect (SCE), which may refer to a phenomenon where an electric potential of a channel region may be affected by the drain voltage.

### SUMMARY

One or more example embodiments of the present disclosure provide a semiconductor device that may reduce leakage current between adjacent source/drain regions by forming lower spacers and voids under the source/drain regions.

However, aspects of the present disclosure are not restricted to those set forth herein. The above and other aspects of the present disclosure may be more apparent to one of ordinary skill in the art to which the present disclosure pertains by referencing the detailed description of the present disclosure given below.

According to an aspect of the present disclosure, a semiconductor device includes a substrate, an active pattern on the substrate and extending in a first horizontal direction, at least one first nanosheet stacked on the active pattern and spaced apart from one another in a vertical direction, at least one second nanosheet stacked on the active pattern and spaced apart from one another in the vertical direction, a trench formed on the active pattern between the at least one first nanosheet and the at least one second nanosheet, a lower spacer disposed along a bottom surface of the trench, a source/drain region on the lower spacer within the trench, and a void formed within the trench between the lower spacer and the source/drain region. The at least one second nanosheet is spaced apart from the at least one first nanosheet in the first horizontal direction. The trench extends into the active pattern. An uppermost surface of the lower spacer is formed at a first level that is lower than a second level of an uppermost surface of the active pattern. An uppermost surface of the void is formed at a third level that is higher than the second level of the uppermost surface of the active pattern.

According to an aspect of the present disclosure, a semiconductor device includes a substrate, an active pattern on the substrate and extending in a first horizontal direction on the substrate, a first gate electrode extending in a second horizontal direction different from the first horizontal direction on the active pattern, a second gate electrode extending in the second horizontal direction on the active pattern, a gate insulating layer disposed on sidewalls of the first gate electrode in the first horizontal direction, a trench formed on the active pattern between the first gate electrode and the second gate electrode, a lower spacer disposed along a bottom surface of the trench, a source/drain region on the lower spacer within the trench, and a void formed within the trench between the lower spacer and the source/drain region. The second gate electrode is spaced apart from the first gate electrode in the first horizontal direction. The trench extends into the active pattern. An uppermost surface of the lower spacer is formed at a first level that is lower than a second level of an uppermost surface of the active pattern. An uppermost surface of the void is formed at a third level that is higher than the second level of the uppermost surface of the active pattern. The source/drain region includes a first layer in contact with sidewalls of the gate insulating layer in the first horizontal direction and the uppermost surface of the lower spacer, a second layer on the first layer, and a third layer on the second layer. At least a portion of the second layer is exposed through the void. At least a portion of the third layer is exposed through the void.

According to an aspect of the present disclosure, a semiconductor device includes a substrate, an active pattern on the substrate and extending in a first horizontal direction, a first plurality of nanosheets stacked on the active pattern and spaced apart from one another in a vertical direction, a second plurality of nanosheets stacked on the active pattern and spaced apart from one another in the vertical direction, a first gate electrode on the active pattern and extending in a second horizontal direction different from the first horizontal direction, a second gate electrode on the active pattern and extending in the second horizontal direction, a first gate insulating layer disposed on sidewalls of the first gate electrode in the first horizontal direction, a second gate insulating layer disposed on sidewalls of the second gate electrode in the first horizontal direction, a trench formed on the active pattern between the first plurality of nanosheets and the second plurality of nanosheets, a lower spacer disposed along a bottom surface of the trench, a source/drain region on the lower spacer within the trench, and a void formed within the trench between the lower spacer and the source/drain region. The second plurality of nanosheets is spaced apart from the first plurality of nanosheets in the first horizontal direction. The first gate electrode at least partially surrounding the first plurality of nanosheets. The second gate electrode is spaced apart from the first gate electrode in the first horizontal direction. The second gate electrode at least partially surrounding the second plurality of nanosheets. The trench extends into the active pattern. An uppermost surface of the lower spacer is formed at a first level that is lower than a second level of an uppermost surface of the active pattern. An uppermost surface of the void is formed at a third level that is higher than the second level of the uppermost surface of the active pattern. A lowermost surface of the void is formed at a fourth level that is lower than the first level of the uppermost surface of the lower spacer. An upper surface of the void is formed convexly toward the source/drain region. The source/drain region includes a first layer in contact with sidewalls of each of the first gate insulating layer and the second gate insulating layer in the first horizontal direction and the uppermost surface of the lower spacer, a second layer on the first layer, and a third layer on the second layer. At least a portion of the second layer is exposed through the void. At least a portion of the third layer is exposed through the void.

It should be noted that the effects of the present disclosure are not limited to those described above, and other effects of the present disclosure may be more apparent from the following description.

### BRIEF DESCRIPTION OF THE DRAWINGS

The above and other aspects, features, and advantages of certain embodiments of the present disclosure may be more apparent from the following description taken in conjunction with the accompanying drawings, in which:

FIG. 1 is a schematic layout view illustrating a semiconductor device, according to some embodiments of the present disclosure;

FIG. 2 is a cross-sectional view taken along line A-A′ of FIG. 1, according to some embodiments of the present disclosure;

FIG. 3 is a cross-sectional view taken along line B-B′ of FIG. 1, according to some embodiments of the present disclosure;

FIGS. 4 to 15 are cross-sectional views illustrating intermediate steps of a method of fabricating a semiconductor device, according to some embodiments of the present disclosure; and

FIGS. 16 to 21 are cross-sectional views illustrating semiconductor devices, according to some embodiments of the present disclosure.

### DETAILED DESCRIPTION

The following description with reference to the accompanying drawings is provided to assist in a comprehensive understanding of embodiments of the present disclosure defined by the claims and their equivalents. Various specific details are included to assist in understanding, however these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, and the like may be replaced with terms, such as “first,” “second,” third” to be used to describe relative positions of elements. The terms “first,” “second,” third” may be used to describe various elements however the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

It is to be understood that the specific order or hierarchy of operations in the processes disclosed are an illustration of exemplary approaches. Based upon design preferences, it is understood that the specific order or hierarchy of operations in the processes may be rearranged. Further, some operations may be combined or omitted. The accompanying claims present elements of the various operations in a sample order, and are not meant to be limited to the specific order or hierarchy presented.

As used herein, each of the terms “Al₂O₃”, “AlN”, “BaSrTiO”, “BaTiO”, “HfAlO”, “HfO₂”, “HfSiO”, “HfZrO”, “La₂O₃”, “LaAlO”, “MoC”, “MoN”, “NbC”, “NbN”, “Ni—Pt”, “PbScTaO”, “PbTiZrO₅”, “PZN”, “SiBC”, “SiBCN”, “SiBN”, “SiCN”, “SiN”, “SiO₂”, “SiOBN”, “SiOC”, “SiOCN”, “SiON”, “SrTiO”, “Ta₂O₅”, “TaAlN”, “TaCN”, “TaTiN”, “Ti”, “TiAl”, “TiAlC”, “TiAlC—N”, “TiAlN”, “TiC”, “TiO₂”, “WC”, “WN”, “Y₂O₃”, “ZrO₂”, “ZrSiO”, and the like may refer to a material made of elements included in each of the terms and is not a chemical formula representing a stoichiometric relationship.

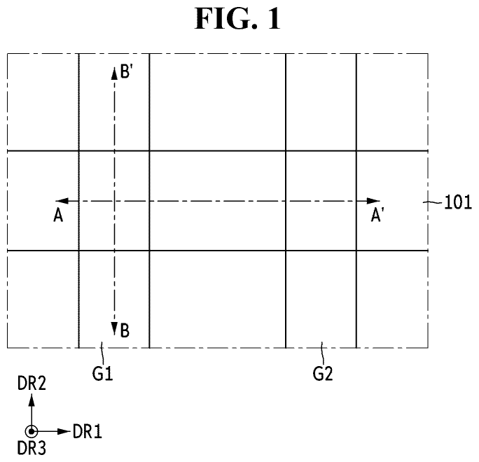

A semiconductor device, according to some embodiments of the present disclosure, is described with reference to FIGS. 1 to 3.

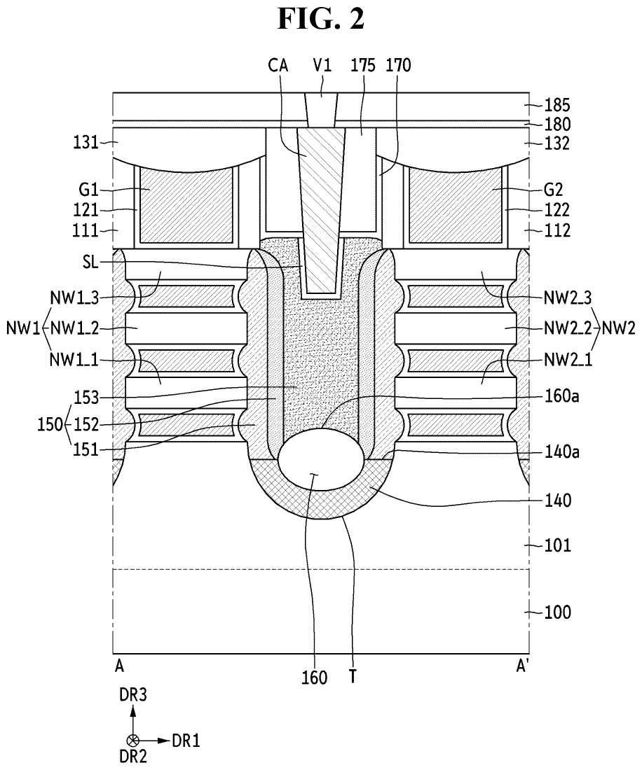

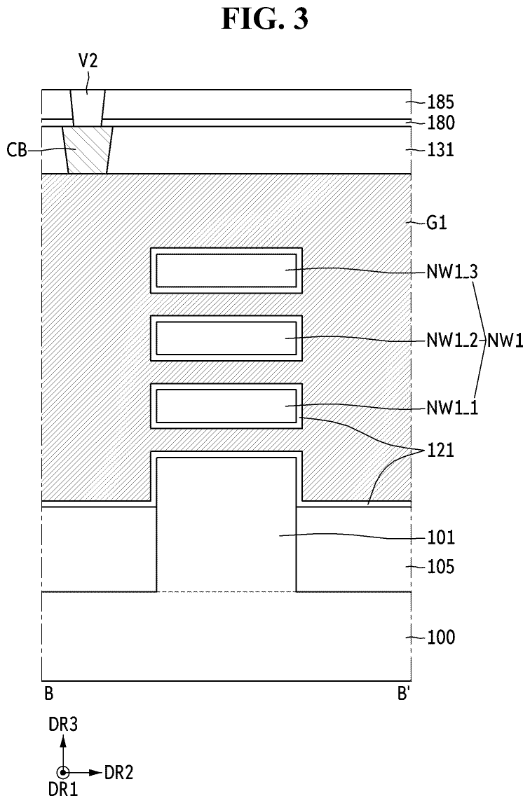

FIG. 1 is a schematic layout view illustrating a semiconductor device, according to some embodiments of the present disclosure. FIG. 2 is a cross-sectional view taken along line A-A′ of FIG. 1, according to some embodiments of the present disclosure. FIG. 3 is a cross-sectional view taken along line B-B′ of FIG. 1, according to some embodiments of the present disclosure.

Referring to FIGS. 1 to 3, the semiconductor device, according to some embodiments of the present disclosure, includes a substrate 100, an active pattern 101, at least one first nanosheet NW1, at least one second nanosheet NW2, a first gate electrode G1, a second gate electrode G2, first gate spacers 111, second gate spacers 112, first gate insulating layers 121, second gate insulating layers 122, first capping patterns 131, second capping patterns 132, a lower spacer 140, a source/drain region 150, a void 160, a first etching stop layer 170, a first interlayer insulating layer 175, a source/drain contact CA, a silicide layer SL, a gate contact CB, a second etching stop layer 180, a second interlayer insulating layer 185, first vias V1, and second vias V2.

The substrate 100 may be and/or may include a silicon (Si) substrate, silicon-on-insulator (SOI), or the like. Alternatively or additionally, the substrate 100 may be and/or may include silicon-germanium (SiGe), SiGe-on-insulator (SGOI), indium antimonide (InSb), a lead telluride (PbTe) compound, indium arsenide (InAs), indium phosphide (InP), gallium arsenide (GaAs), gallium antimonide (GaSb), or the like. However, the present disclosure is not limited thereto.

First and second horizontal directions DR1 and DR2 may refer to directions parallel to the upper surface of the substrate 100. The second horizontal direction DR2 may refer to a direction different from the first horizontal direction DR1. A vertical direction DR3 may refer to a direction perpendicular to both the first and second horizontal directions DR1 and DR2. That is, the vertical direction DR3 may refer to a direction perpendicular to the upper surface of the substrate 100.

The active pattern 101 may extend in the first horizontal direction DR1 on the substrate 100. The active pattern 101 may protrude in the vertical direction DR3 from the upper surface of the substrate 100. For example, the active pattern 101 may be a part of the substrate 100 and may include an epitaxial layer grown from the substrate 100.

A field insulating layer 105 may be disposed on the upper surface of the substrate 100. The field insulating layer 105 may surround the sidewalls of the active pattern 101. For example, the upper surface of the active pattern 101 may protrude in the vertical direction DR3 from the upper surface of the field insulating layer 105, however, the present disclosure is not limited thereto. Alternatively or additionally, the upper surface of the active pattern 101 may be formed on a substantially similar and/or the same plane as the upper surface of the field insulating layer 105. The field insulating layer 105 may include, for example, but not be limited to, an oxide layer, a nitride layer, an oxynitride layer, or a combination thereof.

In some embodiments, the at least one first nanosheet NW1 may include a first plurality of nanosheets. The first plurality of nanosheets NW1 may be stacked on the active pattern 101 and may be spaced apart from one another in the vertical direction DR3. For example, the first plurality of nanosheets NW1 may include a first nanosheet NW1_1, a second nanosheet NW1_2, and a third nanosheet NW1_3, which may be sequentially stacked on the active pattern 101 and may be spaced apart from one another in the vertical direction DR3. That is, the first nanosheet NW1_1 may be spaced apart from the active pattern 101 in the vertical direction DR3, the second nanosheet NW1_2 may be spaced apart from the first nanosheet NW1_1 in the vertical direction DR3, and the third nanosheet NW1_3 may be spaced apart from the second nanosheet NW1_2 in the vertical direction DR3.

In some embodiments, the at least one second nanosheet NW2 may include a second plurality of nanosheets. The second plurality of nanosheets NW2 may be stacked on the active pattern 101 and may be spaced apart from one another in the vertical direction DR3. For example, the second plurality of nanosheets NW2 may include a fourth nanosheet NW2_1, a fifth nanosheet NW2_2, and a sixth nanosheet NW2_3, which may be sequentially stacked on the active pattern 101 and may be spaced apart from one another in the vertical direction DR3. That is, the fourth nanosheet NW2_1 may be spaced apart from the active pattern 101 in the vertical direction DR3, the fifth nanosheet NW2_2 may be spaced apart from the fourth nanosheet NW2_1 in the vertical direction DR3, and the sixth nanosheet NW2_3 may be spaced apart from the fifth nanosheet NW2_2 in the vertical direction DR3.

The second plurality of nanosheets NW2 may be spaced apart from the first plurality of nanosheets NW1 in the first horizontal direction DR1. For example, the first nanosheet NW1_1 may be disposed at a substantially similar and/or the same vertical level as the fourth nanosheet NW2_1. The second nanosheet NW1_2 may be disposed at a substantially similar and/or the same vertical level as the fifth nanosheet NW2_2. The third nanosheet NW1_3 may be disposed at a substantially similar and/or the same vertical level as the sixth nanosheet NW2_3. FIGS. 2 and 3 illustrate that the first plurality of nanosheets NW1 and the second plurality of nanosheets NW2 each include three (3) vertically spaced and stacked nanosheets, however, the present disclosure is not limited thereto. Alternatively or additionally, the first plurality of nanosheets NW1 and the second plurality of nanosheets NW2 may each include four (4) or more vertically spaced and stacked nanosheets. In some embodiments, the first plurality of nanosheets NW1 and the second plurality of nanosheets NW2 may each include silicon (Si), however, the present disclosure is not limited thereto. Alternatively or additionally, in some embodiments, the first plurality of nanosheets NW1 and the second plurality of nanosheets NW2 may each include, but not be limited to, silicon germanium (SiGe) or the like.

The first gate electrode G1 may extend in the second horizontal direction DR2 on the active pattern 101 and the field insulating layer 105. The first gate electrode G1 may surround the first plurality of nanosheets NW1. The second gate electrode G2 may extend in the second horizontal direction DR2 on the active pattern 101 and the field insulating layer 105. The second gate electrode G2 may be spaced apart from the first gate electrode G1 in the first horizontal direction DR1. The second gate electrode G2 may surround the second plurality of nanosheets NW2.

Each of the first and second gate electrodes G1 and G2 may include, for example, but not be limited to, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel-platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or a combination thereof. Each of the first and second gate electrodes G1 and G2 may include, but not be limited to, a conductive metal oxide and/or a conductive metal oxynitride, and/or may include oxidized forms of the aforementioned materials.

The first gate spacers 111 may be disposed on the upper surface of the uppermost nanosheet of the first plurality of nanosheets NW1 and the field insulating layer 105. For example, the first gate spacers 111 may be disposed on the upper surface of the third nanosheet NW1_3 and the field insulating layer 105. The first gate spacers 111 may extend in the second horizontal direction DR2 on both sidewalls, in the first horizontal direction DR1, of the first gate electrode G1. The second gate spacers 112 may be disposed on the upper surface of the uppermost nanosheet of the second plurality of nanosheets NW2 and the field insulating layer 105. For example, the second gate spacers 112 may be disposed on the upper surface of the sixth nanosheet NW2_3 and the field insulating layer 105. The second gate spacers 112 may extend in the second horizontal direction DR2 on both sidewalls, in the first horizontal direction DR1, of the second gate electrode G2. Each of the first and second gate spacers 111 and 112 may include, for example, at least one of silicon nitride (SiN), silicon oxynitride (SiON), silicon oxide (SiO₂), silicon carbonitride (SiCN), silicon oxycarbonitride (SiOCN), silicon boron nitride (SiBN), silicon oxyboron nitride (SiOBN), silicon boron carbide (SiBC), silicon boron carbonitride (SiBCN), silicon oxycarbide (SiOC), or a combination thereof. However, the present disclosure is not limited thereto.

A trench T may be formed between the first and second gate electrodes G1 and G2 on the active pattern 101. The trench T may be formed between the first plurality of nanosheets NW1 and the second plurality of nanosheets NW2 on the active pattern 101. For example, the trench T may extend into the active pattern 101. That is, the bottom surface of the trench T may be lower than the uppermost surface of the active pattern 101. For example, the bottom surface of the trench T may be lower than the upper surface of the field insulating layer 105, however, the present disclosure is not limited thereto. For example, the sidewalls and bottom surface of the trench T may be defined by the sidewalls, in the first horizontal direction DR1, of the first plurality of nanosheets NW1, the sidewalls, in the first horizontal direction DR1, of the second plurality of nanosheets NW2, the first and second gate insulating layers 121 and 122, and the active pattern 101.

The lower spacer 140 may be disposed along the bottom surface of the trench T. For example, the lower spacer 140 may be disposed in a liner shape. For example, in a cross-sectional view taken along the first horizontal direction DR1 in FIG. 2, the lower spacer 140 may have a semi-circular shape. Alternatively or additionally, the lower surface of the lower spacer 140 may be in contact with the active pattern 101. In some embodiments, the upper surface of the lower spacer 140 may be concave toward the active pattern 101. The uppermost surface 140a of the lower spacer 140 may be lower than the uppermost surface of the active pattern 101. FIG. 2 illustrates that an uppermost surface 140a of the lower spacer 140 is formed parallel to the first horizontal direction DR1, however, the present disclosure is not limited thereto. Alternatively or additionally, the uppermost surface 140a of the lower spacer 140 may be inclined with respect to the first horizontal direction DR1.

For example, the lower spacer 140 may be formed as a single layer, however, the present disclosure is not limited thereto. In some embodiments, the thickness, in the vertical direction DR3, of the lower spacer 140 at a lowermost part of the trench T may range from about 2 nanometers (nm) to about 10 nm. For example, the difference in height between the uppermost surface 140a of the lower spacer 140 and the uppermost surface of the active pattern 101 may range from about 2 nm to about 4 nm. The lower spacer 140 may include an insulating material. For example, the lower spacer 140 may include at least one of silicon nitride (SiN), silicon oxynitride (SiON), silicon oxide (SiO₂), silicon carbonitride (SiCN), silicon oxycarbonitride (SiOCN), silicon boron nitride (SiBN), silicon oxyboron nitride (SiOBN), silicon boron carbide (SiBC), silicon boron carbonitride (SiBCN), silicon oxycarbide (SiOC), or a combination thereof. However, the present disclosure is not limited thereto.

The source/drain region 150 may be disposed on the lower spacer 140, within the trench T. For example, the source/drain region 150 may be in contact with the sidewalls, in the first horizontal direction DR1, of the first plurality of nanosheets NW1. The source/drain region 150 may be in contact with the sidewalls, in the first horizontal direction DR1, of the second plurality of nanosheets NW2. For example, the source/drain region 150 may be in contact with the uppermost surface 140a of the lower spacer 140. In some embodiments, at least a portion of the source/drain region 150 may be in contact with the active pattern 101 on the uppermost surface 140a of the lower spacer 140. For example, the uppermost surface of the source/drain region 150 may be formed higher than the upper surface of the third nanosheet NW1_3 and the upper surface of the sixth nanosheet NW2_3.

In some embodiments, at least a portion of the source/drain region 150 may be disposed between the active pattern 101 and the first nanosheet NW1_1. At least a portion of the source/drain region 150 may be disposed between adjacent nanosheets of the first plurality of nanosheets NW1. For example, at least a portion of the source/drain region 150 may be disposed between the first nanosheet NW1_1 and the second nanosheet NW1_2. Alternatively or additionally, at least a portion of the source/drain region 150 may be disposed between the second nanosheet NW1_2 and the third nanosheet NW1_3. For example, at least a portion of the source/drain region 150 may be disposed between the active pattern 101 and the fourth nanosheet NW2_1. Alternatively or additionally, at least a portion of the source/drain region 150 may be disposed between adjacent the second plurality of nanosheets NW2. For example, at least a portion of the source/drain region 150 may be disposed between the fourth nanosheet NW2_1 and the fifth nanosheet NW2_2. As another example, at least a portion of the source/drain region 150 may be disposed between the fifth nanosheet NW2_2 and the sixth nanosheet NW2_3.

In some embodiments, the source/drain region 150 may include a first layer 151, a second layer 152, and a third layer 153. The first layer 151 may be disposed along the sidewalls of the trench T, on the uppermost surface 140a of the lower spacer 140. For example, the first layer 151 may be in contact with the sidewalls, in the first horizontal direction DR1, of the first plurality of nanosheets NW1. The first layer 151 may be in contact with the sidewalls, in the first horizontal direction DR1, of the second plurality of nanosheets NW2. For example, the first layer 151 may be in contact with the uppermost surface 140a of the lower spacer 140. As another example, at least a portion of the first layer 151 may be in contact with the active pattern 101, on the uppermost surface 140a of the lower spacer 140.

In some embodiments, at least a portion of the first layer 151 may be disposed between the active pattern 101 and the first nanosheet NW1_1. Alternatively or additionally, at least a portion of the first layer 151 may be disposed between the first nanosheet NW1_1 and the second nanosheet NW1_2. As another example, at least a portion of the first layer 151 may be disposed between the second nanosheet NW1_2 and the third nanosheet NW1_3. As another example, at least a portion of the first layer 151 may be disposed between the active pattern 101 and the fourth nanosheet NW2_1. As yet another example, at least a portion of the first layer 151 may be disposed between the fourth nanosheet NW2_1 and the fifth nanosheet NW2_2. As yet another example, at least a portion of the first layer 151 may be disposed between the fifth nanosheet NW2_2 and the sixth nanosheet NW2_3.

In some embodiments, the first layer 151 may extend to the lower surfaces of the first gate spacers 111 disposed on the upper surface of the third nanosheet NW1_3. Alternatively or additionally, the first layer 151 may extend to the lower surfaces of the second gate spacers 112 disposed on the upper surface of the sixth nanosheet NW2_3. In some embodiments, the first layer 151 may include undoped silicon (Si), undoped silicon germanium (SiGe), carbon (C)-doped silicon (Si), C-doped silicon germanium (SiGe), or the like. However, the present disclosure is not limited thereto.

The second layer 152 may be disposed on the first layer 151 within the trench T. For example, the second layer 152 may be disposed along the sidewalls of the first layer 151. That is, the second layer 152 may be in contact with the sidewalls of the first layer 151. For example, in the cross-sectional view, taken along the first horizontal direction DR1, of FIG. 2, at least a portion of the second layer 152 may be in contact with the uppermost surface 140a of the lower spacer 140. However, the present disclosure is not limited thereto.

In some embodiments, the second layer 152 may extend to the lower surfaces of the first gate spacers 111 disposed on the upper surface of the third nanosheet NW1_3. Alternatively or additionally, the second layer 152 may extend to the lower surfaces of the second gate spacers 112 disposed on the upper surface of the sixth nanosheet NW2_3. For example, the second layer 152 may include a different material from the first layer 151. In such an example, the second layer 152 may include silicon (Si)-doped with arsenic (As), silicon (Si)-doped with phosphorus (P), silicon (Si)-doped with both arsenic (As) and phosphorus (P), or silicon (Si)-doped with antimony (Sb), or the like. However, the present disclosure is not limited thereto.

The third layer 153 may be disposed on the second layer 152 within the trench T. For example, the third layer 153 may fill the entire trench T, excluding the lower spacer 140, the first layer 151, the second layer 152, and the void 160. As another example, the third layer 153 may be in contact with the sidewalls of the second layer 152. For example, in the cross-sectional view, taken along the first horizontal direction DR1, in FIG. 2, the third layer 153 may not be in contact with the lower spacer 140. That is, in the cross-sectional view, taken along the first horizontal direction DR1, of FIG. 2, the third layer 153 may be spaced apart from the lower spacer 140 in the vertical direction DR3. The third layer 153 may include, but not be limited to, silicon (Si)-doped with P. For example, if the second layer 152 includes silicon (Si)-doped with both arsenic (As) and phosphorus (P) or silicon (Si)-doped with phosphorus (P) alone, the concentration of phosphorus (P) doped in the third layer 153 may be greater than the concentration of phosphorus (P) doped in the second layer 152. These concentrations may be defined in atomic percent (at %) values.

The void 160 may be formed between the lower spacer 140 and the source/drain region 150 within the trench T. For example, through the void 160, a portion of the lower spacer 140 may be exposed. That is, the lower surface of the void 160 may be defined by the lower spacer 140. For example, through the void 160, the uppermost surface 140a of the lower spacer 140 may not be exposed, however, the present disclosure is not limited thereto. Alternatively or additionally, at least a portion of the uppermost surface 140a of the lower spacer 140 may be exposed through the void 160. For example, through the void 160, the second and third layers 152 and 153 may be exposed. That is, the upper surface of the void 160 may be defined by the second and third layers 152 and 153. For example, through the void 160, the first layer 151 may not be exposed, however, the present disclosure is not limited thereto. Alternatively or additionally, at least a portion of the first layer 151 may be exposed through the void 160.

In some embodiments, the upper surface of the void 160 may be formed convexly toward the source/drain region 150. Alternatively or additionally, the lower surface of the void 160 may be formed convexly toward the active pattern 101. For example, the lowermost surface of the void 160 may be formed lower than the uppermost surface 140a of the lower spacer 140. As another example, an uppermost surface 160a of the void 160 may be formed higher than the uppermost surface 140a of the lower spacer 140. As yet another example, the uppermost surface 160a of the void 160 may be formed higher than the upper surface of the active pattern 101. Alternatively or additionally, the uppermost surface 160a of the void 160 may be formed lower than the lower surface of the first nanosheet NW1_1, which may refer to the lowermost nanosheet of the first plurality of nanosheet NW1. Alternatively or additionally, the uppermost surface 160a of the void 160 may be formed lower than the lower surface of the fourth nanosheet NW2_1, which may refer to the lowermost nanosheet of the second plurality of nanosheet NW2. In such embodiments, the ratio of the volume of the void 160 to the combined volume of the void 160 and the source/drain region 150 may range from about 2% to about 5%.

The first gate insulating layer 121 may be disposed on both sidewalls, in the first horizontal direction DR1, of the first gate electrode G1. For example, the first gate insulating layer 121 may be disposed between the first gate electrode G1 and the first gate spacers 111. The first gate insulating layer 121 may be disposed between the first gate electrode G1 and the active pattern 101. The first gate insulating layer 121 may be disposed between the first gate electrode G1 and the field insulating layer 105. The first gate insulating layer 121 may be disposed between the first gate electrode G1 and the first plurality of nanosheets NW1. The first gate insulating layer 121 may be disposed between the first gate electrode G1 and the source/drain region 150. That is, the first gate insulating layer 121 may be disposed between the first gate electrode G1 and the first layer 151. For example, the first gate insulating layer 121 may be in contact with the source/drain region 150. That is, the first gate insulating layer 121 may be in contact with the first layer 151.

The second gate insulating layer 122 may be disposed on both sidewalls, in the first horizontal direction DR1, of the second gate electrode G2. For example, the second gate insulating layer 122 may be disposed between the second gate electrode G2 and the second gate spacers 112. The second gate insulating layer 122 may be disposed between the second gate electrode G2 and the active pattern 101. The second gate insulating layer 122 may be disposed between the second gate electrode G2 and the field insulating layer 105. The second gate insulating layer 122 may be disposed between the second gate electrode G2 and the second plurality of nanosheets NW2. The second gate insulating layer 122 may be disposed between the second gate electrode G2 and the source/drain region 150. That is, the second gate insulating layer 122 may be disposed between the second gate electrode G2 and the first layer 151. For example, the second gate insulating layer 122 may be in contact with the source/drain region 150. That is, the second gate insulating layer 122 may be in contact with the first layer 151.

The first and second gate insulating layers 121 and 122 may include, but not be limited to, at least one of silicon oxide (SiO₂), silicon oxynitride (SiON), silicon nitride (SiN), a high-k material with a greater dielectric constant than silicon oxide (SiO₂), or the like. The high-k material may include, for example, but not be limited to, at least one of hafnium oxide (HfO₂), hafnium silicon oxide (HfSiO), hafnium aluminum oxide (HfAlO), lanthanum oxide (La₂O₃), lanthanum aluminum oxide (LaAlO), zirconium oxide (ZrO₂), zirconium silicon oxide (ZrSiO), tantalum oxide (Ta₂O₅), titanium oxide (TiO₂), barium strontium titanium (BST) oxide (BaSrTiO), barium titanium oxide (BaTiO), strontium titanium oxide (SrTiO), yttrium oxide (Y₂O₃), aluminum oxide (Al₂O₃), lead scandium tantalum (PST) oxide (PbScTaO), lead zinc niobate (PZN), or the like.

The semiconductor device, according to some embodiments of the present disclosure, may include negative capacitance (NC) field-effect transistors (FETs) using negative capacitors. For example, each of the first and second gate insulating layers 121 and 122 may include a ferroelectric material film having ferroelectric properties and a paraelectric material film having paraelectric properties.

The ferroelectric material film may have a negative capacitance, and the paraelectric material film may have a positive capacitance. For example, if two (2) or more capacitors are connected in series and have positive capacitance, the total capacitance of the two (2) or more capacitors may be lower than the capacitance of each of the two (2) or more capacitors. Alternatively, if at least one (1) of the two (2) or more capacitors has negative capacitance, the total capacitance of the two (2) or more capacitors may have a positive value and may be greater than the absolute value of the capacitance of each of the two (2) or more capacitors.

If the ferroelectric material film having a negative capacitance and the paraelectric material film having a positive capacitance are connected in series, the total capacitance of the ferroelectric material film and the paraelectric material film may increase. Accordingly, a transistor having the ferroelectric material film may have a sub-threshold swing (SS) of less than 60 mV/decade at room temperature.

The ferroelectric material film may have ferroelectric properties. The ferroelectric material film may include, for example, but not be limited to, at least one of hafnium oxide (HfO₂), hafnium zirconium oxide (HfZrO), barium strontium titanium oxide (BaSrTiO), barium titanium oxide (BaTiO), lead zirconium titanium oxide (PbTiZrO₅), or the like. For example, the hafnium zirconium oxide (HfZrO) may be and/or may include a material obtained by doping hafnium oxide (HfO₂) with zirconium (Zr). In another example, the hafnium zirconium oxide (HfZrO) may be and/or may include a compound of hafnium (Hf), zirconium (Zr), and oxygen (O).

The ferroelectric material film may further include a dopant. For example, the dopant may include, but not be limited to, at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), tin (Sn), or the like. The type of dopant may vary depending on the type of material of the ferroelectric material film.

If the ferroelectric material film includes hafnium oxide (HfO₂), the dopant of the ferroelectric material film may include, for example, at least one of gadolinium (Gd), silicon (Si), zirconium (Zr), aluminum (Al), and yttrium (Y).

If the dopant of the ferroelectric material film is aluminum (Al), the ferroelectric material film may include about 3 at % to about 8 at % of aluminum (Al). As used herein, the ratio of the dopant in the ferroelectric material film may refer to the ratio of the sum of the amounts of hafnium (Hf) and aluminum (Al) to the amount of aluminum (Al) in the ferroelectric material film.

If the dopant of the ferroelectric material film is silicon (Si), the ferroelectric material film may include about 2 at % to about 10 at % of silicon (Si). If the dopant of the ferroelectric material film is yttrium (Y), the ferroelectric material film may include about 2 at % to about 10 at % of yttrium (Y). If the dopant of the ferroelectric material film is gadolinium (Gd), the ferroelectric material film may include about 1 at % to about 7 at % of gadolinium (Gd). If the dopant of the ferroelectric material film is zirconium (Zr), the ferroelectric material film may include about 50 at % to about 80 at % of zirconium (Zr).

The paraelectric material film may include paraelectric properties. The paraelectric material film may include, for example, but not be limited to, at least one of silicon oxide (SiO₂), a high-k metal oxide, or the like. The high-k metal oxide may include, for example, at least one of hafnium oxide (HfO₂), zirconium oxide (ZrO₂), and aluminum oxide (Al₂O₃). However, the present disclosure is not limited thereto.

The ferroelectric material film and the paraelectric material film may include a substantially similar and/or the same material. The ferroelectric material film may have ferroelectric properties. Alternatively or additionally, the paraelectric material film may not have ferroelectric properties. For example, if the ferroelectric material film and the paraelectric material film include hafnium oxide (HfO₂), the hafnium oxide (HfO₂) included in the ferroelectric material film may have a different crystalline structure from the hafnium oxide (HfO₂) included in the paraelectric material film.

The ferroelectric material film may be thick enough to exhibit ferroelectric properties. The ferroelectric material film may have a thickness of, for example, about 0.5 nm to about 10 nm. However, the present disclosure is not limited thereto. A critical thickness that may exhibit ferroelectric properties may vary depending on the type of ferroelectric material, and thus, the thickness of the ferroelectric material film may vary depending on the type of ferroelectric material included in the ferroelectric material film.

For example, each of the first and second gate insulating layers 121 and 122 may include a ferroelectric material film. As another example, each of the first and second gate insulating layers 121 and 122 may include a plurality of ferroelectric material films that may be spaced apart from each other. Each of the first and second gate insulating layers 121 and 122 may include a stack of a plurality of ferroelectric material films and a plurality of paraelectric material films that may be alternately stacked with the ferroelectric material films.

The first etching stop layer 170 may be disposed on the sidewalls, in the first horizontal direction DR1, of the first gate spacers 111 and the second gate spacers 112. Alternatively or additionally, the first etching stop layer 170 may be disposed on the upper surface of the source/drain region 150. In some embodiments, the first etching stop layer 170 may be disposed on the sidewalls, in the second horizontal direction DR2, of the source/drain region 150. For example, the first etching stop layer 170 may be conformally formed. The first etching stop layer 170 may include, for example, at least one of aluminum oxide (Al₂O₃), aluminum nitride (AlN), hafnium oxide (HfO₂), zirconium oxide (ZrO₂), silicon oxide (SiO₂), silicon nitride (SiN), silicon oxynitride (SiON), a low-k material, or the like. However, the present disclosure is not limited thereto.

The first capping pattern 131 may extend in the second horizontal direction DR2 over each of the first gate spacers 111, the first gate insulating layer 121, and the first gate electrode G1. The second capping pattern 132 may extend in the second horizontal direction DR2 over each of the second gate spacers 112, the second gate insulating layer 122, and the second gate electrode G2. For example, the lower surfaces of the first and second capping patterns 131 and 132 may be in contact with the first etching stop layer 170, however, the present disclosure is not limited thereto. Alternatively or additionally, the sidewalls of the first and second capping patterns 131 and 132 may be in contact with the first etching stop layer 170. The first and second capping patterns 131 and 132 may include, for example, at least one of silicon nitride (SiN), silicon oxynitride (SiON), silicon oxide (SiO₂), silicon carbonitride (SiCN), silicon oxycarbonitride (SiOCN), or a combination thereof. However, the present disclosure is not limited thereto.

The first interlayer insulating layer 175 may be disposed on the first etching stop layer 170. The first interlayer insulating layer 175 may be disposed on the sidewalls of each of the first and second capping patterns 131 and 132. The first interlayer insulating layer 175 may cover the source/drain region 150 on the field insulating layer 105. For example, the upper surface of the first interlayer insulating layer 175 may be formed on a substantially similar and/or the same plane as the upper surfaces of the first and second capping patterns 131 and 132. The first interlayer insulating layer 175 may include, for example, at least one of silicon oxide (SiO₂), silicon nitride (SiN), silicon oxynitride (SiON), a low-k material, or the like. However, the present disclosure is not limited thereto.

The source/drain contact CA may be disposed between the first and second gate electrodes G1 and G2. The source/drain contact CA may be disposed above the source/drain region 150. The source/drain contact CA may extend into the source/drain region 150 by penetrating the first interlayer insulating layer 175 and the first etching stop layer 170 in the vertical direction DR3. The source/drain contact CA may be electrically connected to the source/drain region 150. In FIG. 2, the source/drain contact CA is illustrated as being formed as a single layer, however, the present disclosure is not limited thereto. Alternatively or additionally, the source/drain contact CA may be formed as a multilayer. For example, the upper surface of the source/drain contact CA may be formed on a substantially similar and/or the same plane as the upper surface of the first interlayer insulating layer 175, however, the present disclosure is not limited thereto. Alternatively or additionally, the upper surface of the source/drain contact CA may be formed higher than the upper surface of the first interlayer insulating layer 175. The source/drain contact CA may be and/or may include a conductive material. The silicide layer SL may be disposed between the source/drain contact CA and the source/drain region 150. The silicide layer SL may be disposed along the boundary between the source/drain contact CA and the source/drain region 150. For example, the silicide layer SL may include a metal silicide material. However, the present disclosure is not limited thereto.

The gate contact CB may be located above the first gate electrode G1. The gate contact CB may be connected to the first gate electrode G1 by penetrating the first capping pattern 131 in the vertical direction DR3. In FIG. 3, the gate contact CB is illustrated as being formed as a single layer, however, the present disclosure is not limited thereto. Alternatively or additionally, the gate contact CB may be formed as a multilayer. For example, the upper surface of the gate contact CB may be formed on a substantially similar and/or the same plane as the upper surfaces of the source/drain contact CA and the first interlayer insulating layer 175, however, the present disclosure is not limited thereto. The gate contact CB may include a conductive material. However, the present disclosure is not limited thereto.

The second etching stop layer 180 may be disposed on the upper surfaces of the source/drain contact CA, the first and second capping patterns 131 and 132, and the first interlayer insulating layer 175. In FIGS. 2 and 3, the second etching stop layer 180 is illustrated as being formed as a single layer, however, the present disclosure is not limited thereto. Alternatively or additionally, the second etching stop layer 180 may be formed as a multilayer. The second etching stop layer 180 may include, for example, at least one of aluminum oxide (Al₂O₃), aluminum nitride (AlN), hafnium oxide (HfO₂), zirconium oxide (ZrO₂), silicon oxide (SiO₂), silicon nitride (SiN), silicon oxynitride (SiON), a low-k material, or the like. However, the present disclosure is not limited thereto. The second interlayer insulating layer 185 may be disposed on the second etching stop layer 180. The second interlayer insulating layer 185 may include, but not be limited to, at least one of silicon oxide (SiO₂), silicon nitride (SiN), silicon oxynitride (SiON), a low-k material, or the like.

The first via V1 may be connected to the source/drain contact CA by penetrating the second interlayer insulating layer 185 and the second etching stop layer 180 in the vertical direction DR3. Similarly, the second via V2 may be connected to the gate contact CB by penetrating the second interlayer insulating layer 185 and the second etching stop layer 180 in the vertical direction DR3. In FIGS. 2 and 3, the first and second vias V1 and V2 are illustrated as being formed as single layers, however, the present disclosure is not limited thereto. Alternatively or additionally, the first and second vias V1 and V2 may be formed as multilayers. The first and second vias V1 and V2 may include a conductive material. However, the present disclosure is not limited thereto.

The semiconductor device, according to some embodiments of the present disclosure, may have the lower spacer 140 under the source/drain region 150, thereby potentially reducing leakage current with a neighboring source/drain region. Alternatively or additionally, the semiconductor device, according to some embodiments of the present disclosure, may have the void 160 between the lower spacer 140 and the source/drain region 150, thereby potentially reducing leakage current with the neighboring source/drain region.

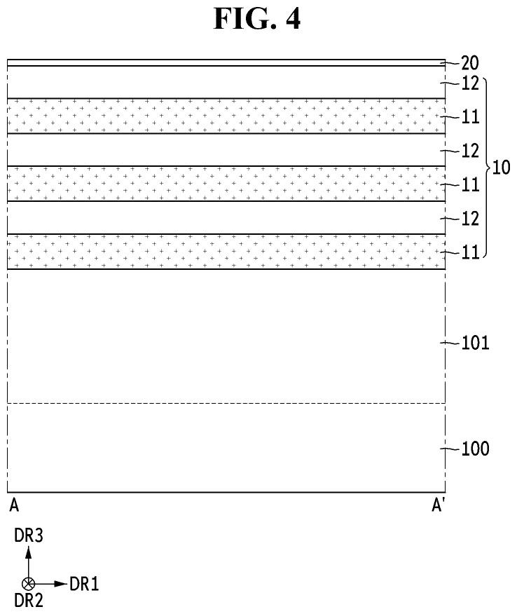

A method of manufacturing a semiconductor device, according to some embodiments of the present disclosure, is described with reference to FIGS. 4 to 15.

FIGS. 4 to 15 are cross-sectional views illustrating intermediate steps of a method of fabricating a semiconductor device, according to some embodiments of the present disclosure.

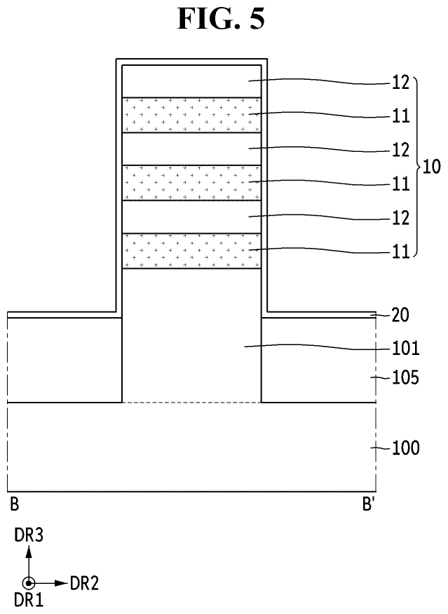

Referring to FIGS. 4 and 5, a stacked structure 10 may be formed on a substrate 100. The stacked structure 10 may include first semiconductor layers 11 and second semiconductor layers 12, which may be stacked on the upper surface of the substrate 100, alternating with the first semiconductor layers 11. For example, the first semiconductor layers 11 may be formed at the top of the stacked structure 10, and the second semiconductor layers 12 may be formed at the bottom of the second semiconductor layer 22. However, the present disclosure is not limited thereto. Alternatively or additionally, the first semiconductor layers 11 may be formed at the top of the stacked structure 10. The first semiconductor layers 11 may include, for example, silicon germanium (SiGe). The second semiconductor layers 12 may include, for example, silicon (Si) or the like. However, the present disclosure is not limited thereto.

Thereafter, the stacked structure 10 may be partially etched. During the etching of the stacked structure 10, the substrate 100 may also be partially etched. Through the etching process, an active pattern 101 may be defined on the upper surface of the substrate 100, below the stacked structure 10. The active pattern 101 may extend in the first horizontal direction DR1. Thereafter, a field insulating layer 105 may be formed on the upper surface of the substrate 100. The field insulating layer 105 may surround the sidewalls of the active pattern 101. For example, the upper surface of the active pattern 101 may be formed higher than the upper surface of the field insulating layer 105. Thereafter, a pad oxide layer 20 may be formed to cover the upper surface of the field insulating layer 105, the exposed sidewalls of the active pattern 101, and the sidewalls and upper surface of the stacked structure 10. For example, the pad oxide layer 20 may be conformally formed. The pad oxide layer 20 may include, for example, silicon oxide (SiO₂) or the like. However, the present disclosure is not limited thereto.

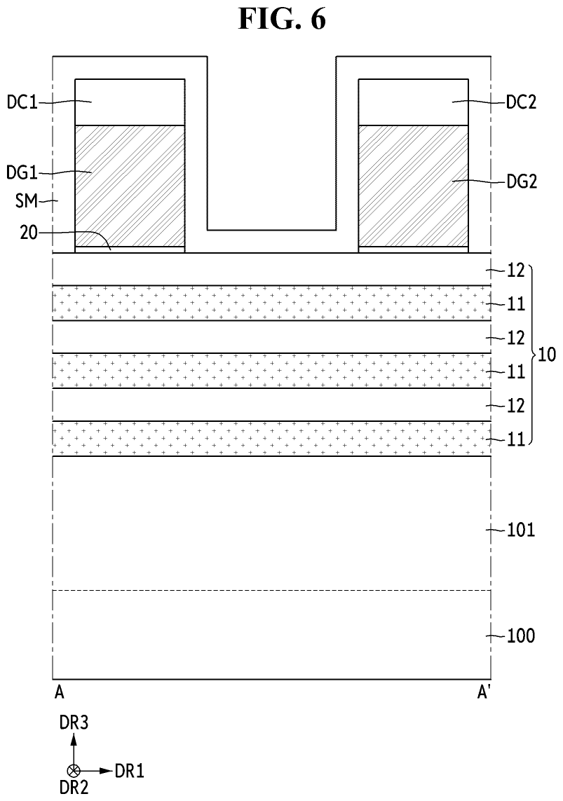

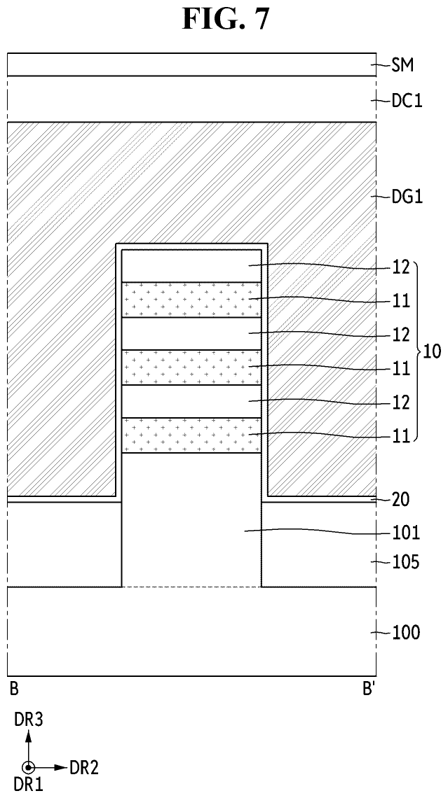

Referring to FIGS. 6 and 7, first dummy gates DG1 and second dummy gates DG2, which may extend in the second horizontal direction DR2, and first dummy capping patterns DC1 and second dummy capping patterns DC2, which may extend in the second horizontal direction DR2, may be formed on the pad oxide layer 20, on the stacked structure 10 and the field insulating layer 105. The first dummy capping pattern DC1 may be formed on the first dummy gate DG1. The second dummy capping pattern DC2 may be formed on the third dummy gate DG3. The second dummy gate DG2 and the second dummy capping pattern DC2 may be spaced apart from the first dummy gate DG1 and the first dummy capping patterns DC1, respectively, in the first horizontal direction DR1. During the formation of the first and second dummy gates DG1 and DG2 and the first and second dummy capping patterns DC1 and DC2, the entire pad oxide layer 20 may be etched, except for portions that may overlap with the first and second dummy gates DG1 and DG2 in the vertical direction DR3.

Thereafter, a spacer material layer SM may be formed to cover the sidewalls and upper surfaces of the first and second dummy gates DG1 and DG2, the first and second dummy capping patterns DC1 and DC2, the exposed sidewalls and upper surfaces of the stacked structure 10, and the upper surface of the field insulating layer 105. For example, the spacer material layer SM may be conformally formed. The spacer material layer SM may include, for example, silicon nitride (SiN), silicon oxynitride (SiON), silicon oxide (SiO₂), silicon carbonitride (SiCN), silicon oxycarbonitride (SiOCN), silicon boron nitride (SiBN), silicon oxyboron nitride (SiOBN), silicon boron carbide (SiBC), silicon boron carbonitride (SiBCN), silicon oxycarbide (SiOC), or a combination thereof. However, the present disclosure is not limited thereto.

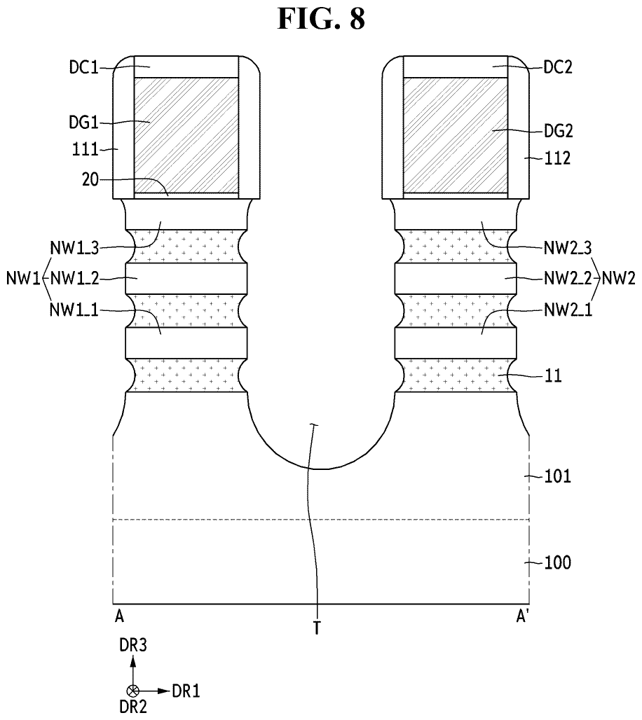

Referring to FIG. 8, the stacked structure 10 may be etched using the first and second dummy capping patterns DC1 and DC2 and the first and second dummy gates DG1 and DG2 as a mask, thereby forming a trench T. For example, the trench T may extend into the active pattern 101. During the formation of the trench T, portions of the spacer material layer SM formed on the upper surfaces of the first and second dummy capping patterns DC1 and DC2 and portions of the first and second dummy capping patterns DC1 and DC2 may be etched. Portions of the spacer material layer SM that remain on the sidewalls of the first dummy capping pattern DC1 and the first dummy gate DG1 may be defined as first gate spacers 111. Similarly, portions of the spacer material layer SM that remain on the sidewalls of the second dummy capping pattern DC2 and the second dummy gate DG2 may be defined as second gate spacers 112.

After the formation of the trench T, the second semiconductor layers 12 that remain below the first dummy gate DG1 may be defined as the first plurality of nanosheets NW1. Alternatively or additionally, after the formation of the trench T, the second semiconductor layers 12 that remain below the second dummy gate DG2 may be defined as the second plurality of nanosheets NW2. For example, during the formation of the trench T, the sidewalls, in the first horizontal direction DR1, of the first semiconductor layers 11 may be etched more than the sidewalls, in the first horizontal direction DR1, of the second semiconductor layers 12. As a result, the sidewalls, in the first horizontal direction DR1, of the first semiconductor layers 11 may be recessed more than the sidewalls, in the first horizontal direction DR1, of the first and second plurality of nanosheets NW1 and NW2.

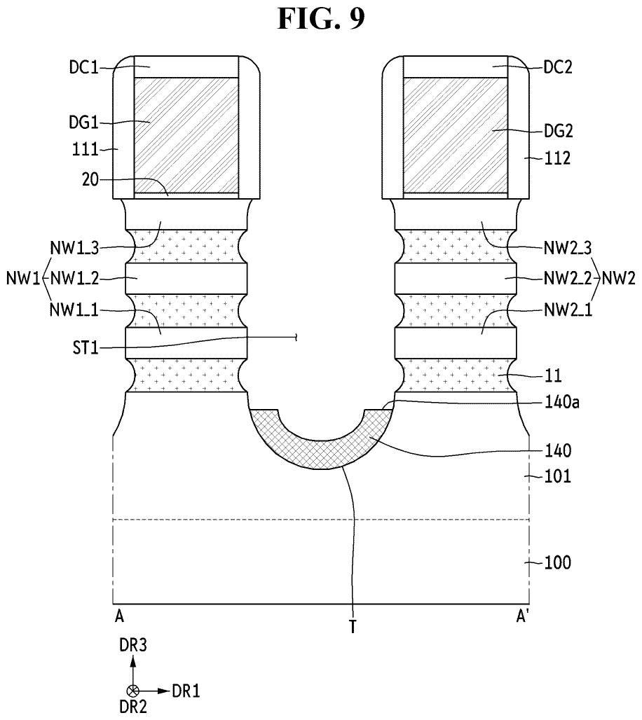

Referring to FIG. 9, a lower spacer 140 may be formed along the bottom surface of the trench T. For example, the lower spacer 140 may be arranged in a liner shape. For example, in a cross-sectional view, taken along the first horizontal direction DR1, in FIG. 9, the lower spacer 140 may have a semi-circular shape. For example, the lower surface of the lower spacer 140 may be in contact with the active pattern 101. In some embodiments, the upper surface of the lower spacer 140 may be formed concavely toward the active pattern 101. For example, an uppermost surface 140a of the lower spacer 140 may be formed lower than the uppermost surface of the active pattern 101. The trench formed on the upper surface of the lower spacer 140 within the trench T may be defined as a first source/drain trench ST1. For example, at least a portion of the active pattern 101 may be exposed through the first source/drain trench ST1 on the uppermost surface 140a of the lower spacer 140.

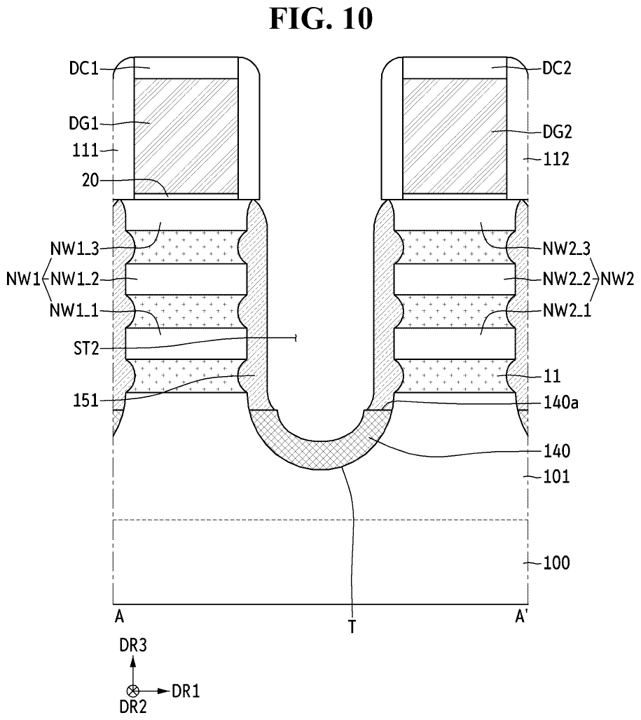

Referring to FIG. 10, a first layer 151 may be formed along the sidewalls of the first source/drain trench ST1. For example, the first layer 151 may be disposed along the sidewalls of the first source/drain trench ST1 on the uppermost surface 140a of the lower spacer 140. That is, the first layer 151 may be in contact with the sidewalls of the first plurality of nanosheets NW1 in the first horizontal direction DR1. The first layer 151 may be in contact with the sidewalls, in the first horizontal direction DR1, of the second plurality of nanosheets NW2. For example, the first layer 151 may be in contact with the sidewalls, in the first horizontal direction DR1, of the first semiconductor layers 11. As another example, the first layer 151 may be in contact with the uppermost surface 140a of the lower spacer 140. As yet another example, at least a portion of the first layer 151 may be in contact with the active pattern 101 on the uppermost surface 140a of the lower spacer 140.

As shown in FIG. 10, in a cross-sectional view, taken along the first horizontal direction DR1, the first layer 151 may not be formed on the upper surface of the lower spacer 140, which may be concavely formed toward the active pattern 101. The trench formed between portions of the first layer 151 within the first source/drain trench ST1 may be defined as a second source/drain trench ST2. For example, the upper surface of the lower spacer 140, which is concavely formed toward the active pattern 101, may be exposed through the second source/drain trench ST2.

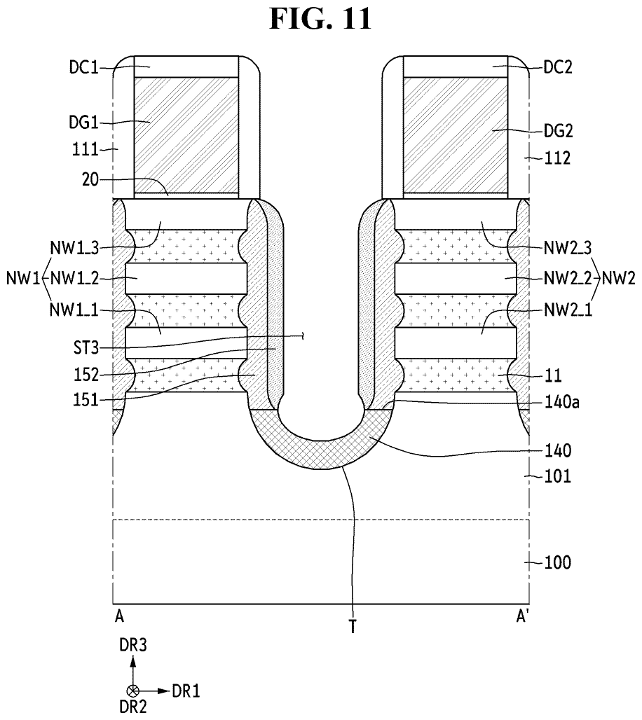

Referring to FIG. 11, a second layer 152 may be formed along the sidewalls of the second source/drain trench ST2. For example, the second layer 152 may be in contact with the sidewalls of the first layer 151. As shown in FIG. 11, in a cross-sectional view, taken along the first horizontal direction DR1, the second layer 152 may not be formed on the upper surface of the lower spacer 140, which may be concavely formed toward the active pattern 101. The trench formed between portions of the second layer 152 within the second source/drain trench ST2 may be defined as a third source/drain trench ST3. For example, the upper surface of the lower spacer 140, which is concavely formed toward the active pattern 101, may be exposed through the third source/drain trench ST3. For example, the sidewalls of the second layer 152 that overlap with the upper surface of the lower spacer 140 in the vertical direction DR3 may have an inclined profile.

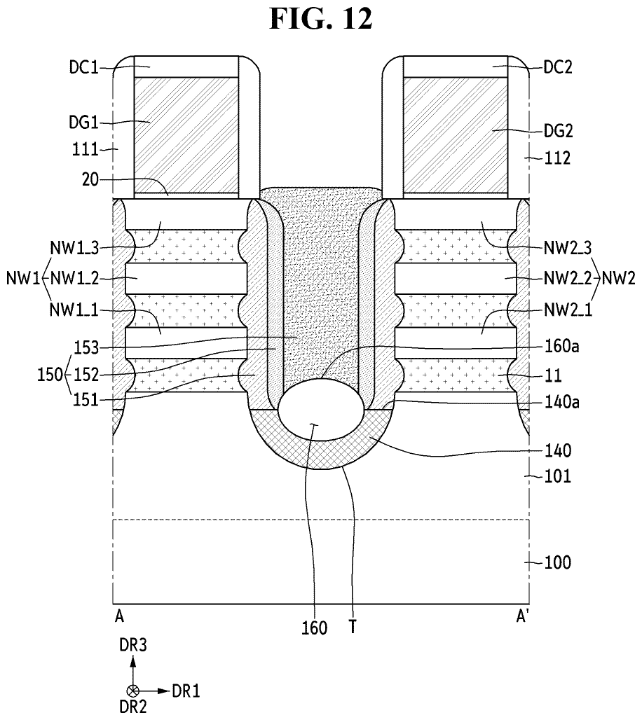

Referring to FIG. 12, a third layer 153 may be formed on the second layer 152 within the third source/drain trench ST3. As a result, a source/drain region 150 including the first to third layers 151 to 153 may be formed. As shown in FIG. 12, in a cross-sectional view, taken along the first horizontal direction DR1, the lower surface of the third layer 153 may be formed concavely toward the upper surface of the third layer 153. For example, after the formation of the third layer 153, a void 160 may be formed between the upper surface of the lower spacer 140, which may be concavely formed toward the active pattern 101, and the lower surface of the source/drain region 150.

For example, the lower surface of the void 160 may be defined by the lower spacer 140. Alternatively or additionally, the upper surface of the void 160 may be defined by the second and third layers 152 and 153. For example, the upper surface of the void 160 may be formed convexly toward the source/drain region 150. Alternatively or additionally, the lower surface of the void 160 may be formed convexly toward the active pattern 101. For example, the lowermost surface of the void 160 may be formed lower than the uppermost surface 140a of the lower spacer 140. For example, an uppermost surface 160a of the void 160 may be formed higher than the uppermost surface 140a of the lower spacer 140. As another example, the uppermost surface 160a of the void 160 may be formed higher than the uppermost surface of the active pattern 101. As yet another example, the uppermost surface 160a of the void 160 may be formed lower than the lower surface of the first-first nanosheet NW1_1 and the lower surface of the fourth nanosheet NW2_1.

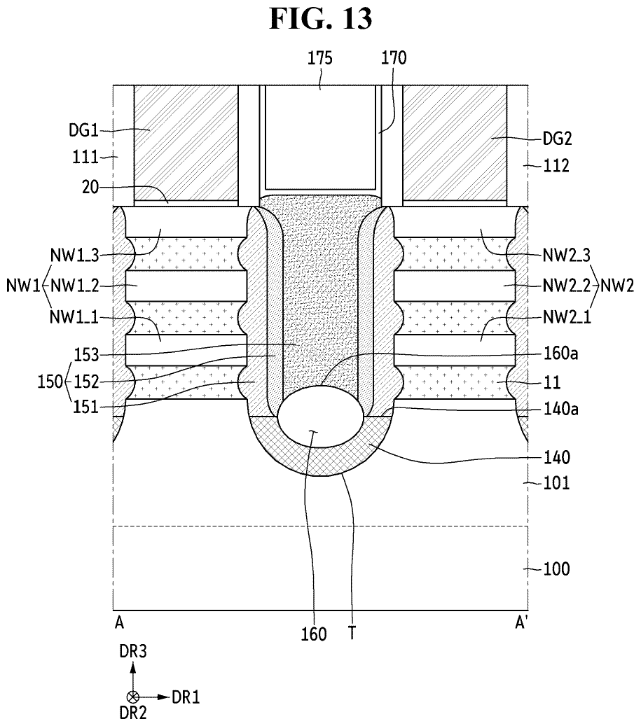

Referring to FIG. 13, a first etching stop layer 170 may be formed on the upper surface of the exposed field insulating layer 105, the sidewalls of the exposed first gate spacers 111 and second gate spacers 112, the upper surfaces of the exposed first and second dummy capping patterns DC1 and DC2, and the surface of the exposed source/drain region 150. Thereafter, a first interlayer insulating layer 175 may be formed on the first etching stop layer 170. Thereafter, a planarization process may be performed, exposing the upper surfaces of the first and second dummy gates DG1 and DG2.

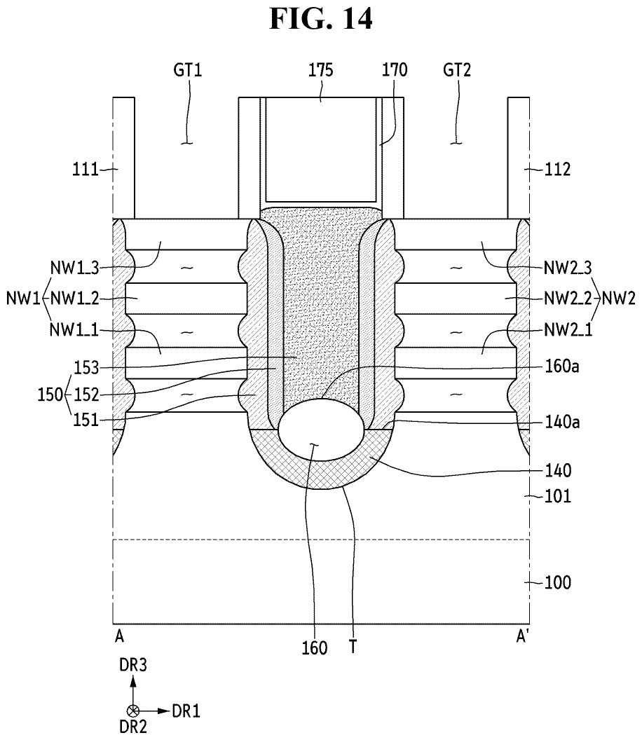

Referring to FIG. 14, the first and second dummy gates DG1 and DG2, the pad oxide layer 20, and the first semiconductor layer 11 may be etched. The regions where the first dummy gate DG1, the pad oxide layer 20, and the first semiconductor layers 11 have been etched may be defined as a first gate trench GT1. Alternatively or additionally, the regions where the second dummy gate DG2, the pad oxide layer 20, and the first semiconductor layer 11 have been etched may be defined as a second gate trench GT2.

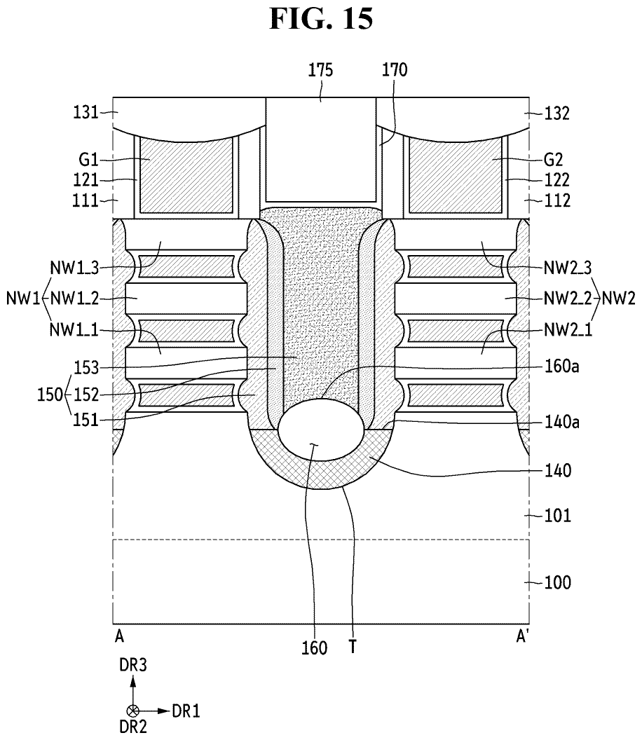

Referring to FIG. 15, a first gate insulating layer 121, a first gate electrode G1, and a first capping pattern 131 may be sequentially formed within the first gate trench GT1. Alternatively or additionally, a second gate insulating layer 122, a second gate electrode G2, and a second capping pattern 132 may be sequentially formed within the second gate trench GT2. For example, the first gate electrode G1 may surround the first plurality of nanosheets NW1. The second gate electrode G2 may surround the second plurality of nanosheets NW2.

Referring to FIGS. 2 and 3, a source/drain contact CA may be formed on the source/drain region 150. The source/drain contact CA may penetrate the first interlayer insulating layer 175 and the first etching stop layer 170 in the vertical direction DR3, extending into the source/drain region 150. Alternatively or additionally, a silicide layer SL may be formed between the source/drain region 150 and the source/drain contact CA. Furthermore, a gate contact CB may be formed to penetrate the first capping pattern 131 in the vertical direction DR3 and be connected to the first gate electrode G1.

Thereafter, a second etching stop layer 180 and a second interlayer insulating layer 185 may be sequentially formed on the upper surfaces of the first interlayer insulating layer 175, the first and second capping patterns 131 and 132, and the source/drain contact CA. Thereafter, a first via V1 may be formed to penetrate the second etching stop layer 180 and the second interlayer insulating layer 185 in the vertical direction DR3 and be connected to the source/drain contact CA. Alternatively or additionally, a second via V2 may be formed to penetrate the second etching stop layer 180 and the second interlayer insulating layer 185 in the vertical direction DR3 and be connected to the gate contact CB. In this manner, the semiconductor device illustrated in FIGS. 2 and 3 may be fabricated.

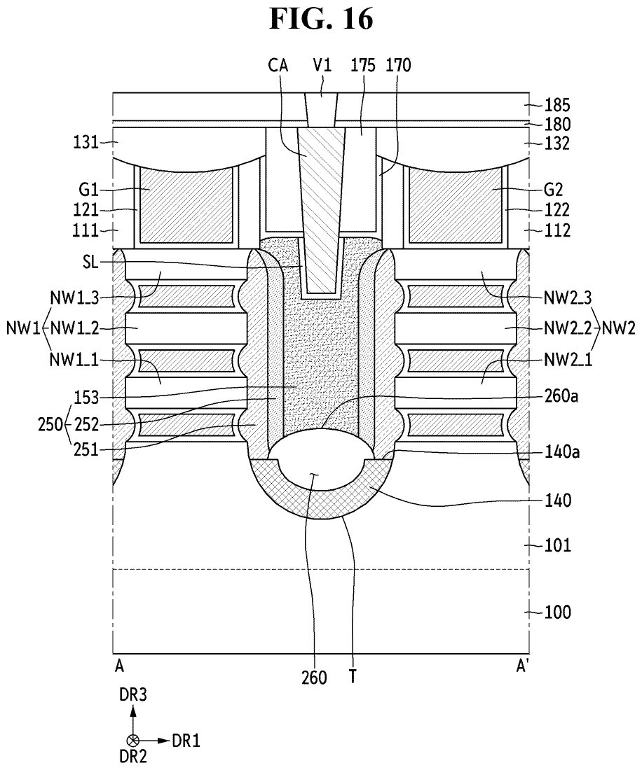

A semiconductor device, according to some embodiments of the present disclosure, is described with reference to FIG. 16, focusing on the differences from the semiconductor device depicted in FIGS. 1 to 3.

FIG. 16 is a cross-sectional view illustrating a semiconductor device, according to some embodiments of the present disclosure. The semiconductor device of FIG. 16 may include and/or may be similar in many respects to the semiconductor device described above with reference to FIGS. 1 to 3, and may include additional features not mentioned above. Consequently, repeated descriptions of the semiconductor device of FIG. 16 described above with reference to FIGS. 1 to 3 may be omitted for the sake of brevity.

Referring to FIG. 16, at least a portion of a void 260 may overlap with an uppermost surface 140a of a lower spacer 140 in the vertical direction DR3.

For example, a source/drain region 250 may include a first layer 251, a second layer 252, and a third layer 153. Alternatively or additionally, at least a portion of the void 260 may be formed on the uppermost surface 140a of the lower spacer 140. For example, through the void 260, the first to third layers 251 to 153 may be exposed. That is, the upper surface of the void 260 may be defined by the first to third layers 251 to 153. As shown in FIG. 16, in a cross-sectional view, taken along the first horizontal direction DR1, the second layer 252 may be spaced apart from the uppermost surface 140a of the lower spacer 140 in the vertical direction DR3.

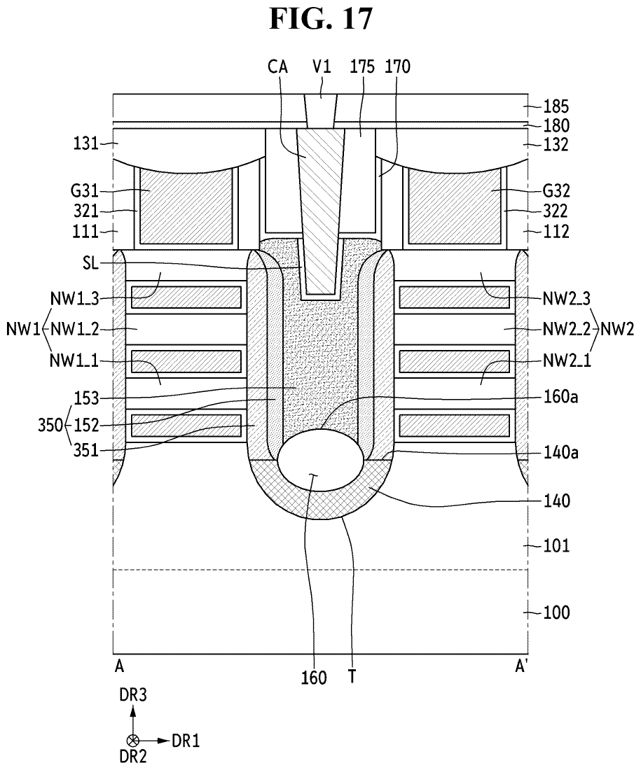

A semiconductor device, according to some embodiments of the present disclosure, is described with reference to FIG. 17, focusing on the differences from the semiconductor device depicted in FIGS. 1 to 3.

FIG. 17 is a cross-sectional view illustrating a semiconductor device according to some embodiments of the present disclosure. The semiconductor device of FIG. 17 may include and/or may be similar in many respects to the semiconductor device described above with reference to FIGS. 1 to 3, and may include additional features not mentioned above. Consequently, repeated descriptions of the semiconductor device of FIG. 17 described above with reference to FIGS. 1 to 3 may be omitted for the sake of brevity.

Referring to FIG. 17, the sidewalls, in the first horizontal direction DR1, of a first gate insulating layer 321 being in contact with a source/drain region 350 may be aligned with the sidewalls, in the first horizontal direction DR1, of first plurality of nanosheets NW1. Alternatively or additionally, the sidewalls, in the first horizontal direction DR1, of a second gate insulating layer 322 being in contact with the source/drain region 350 may be aligned with the sidewalls, in the first horizontal direction DR1, of second plurality of nanosheets NW2.

For example, the sidewalls, in the first horizontal direction DR1, of the first gate insulating layer 321, disposed between a first gate electrode G31 and a first layer 351, may be aligned with the sidewalls, in the first horizontal direction DR1, of the first plurality of nanosheets NW1. Alternatively or additionally, the sidewalls of the second gate insulating layer 322, disposed between a second gate electrode G32 and the first layer 351, may be aligned with the sidewalls, in the first horizontal direction DR1, of the second plurality of nanosheets NW2. As used herein, the term aligned may refer to as having a continuous inclined profile.

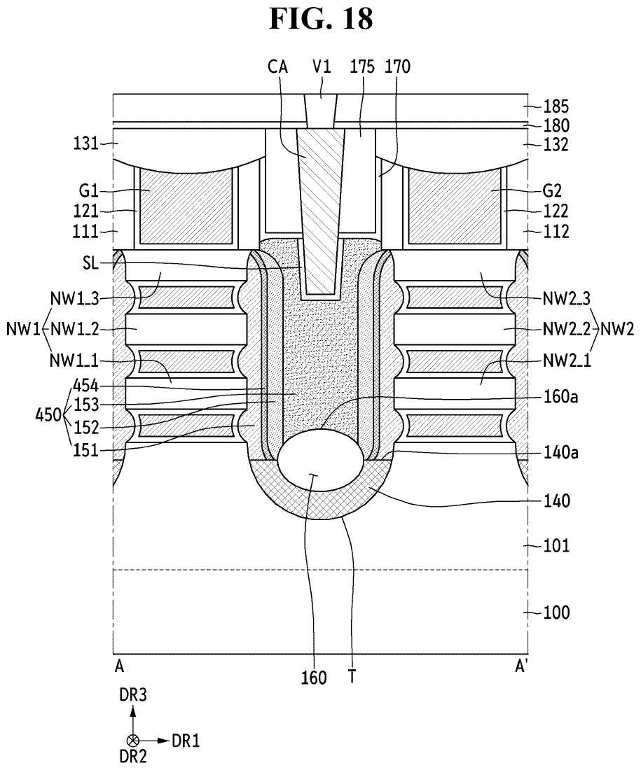

A semiconductor device, according to some embodiments of the present disclosure, is described with reference to FIG. 18, focusing on the differences from the semiconductor device depicted in FIGS. 1 to 3.

FIG. 18 is a cross-sectional view illustrating a semiconductor device, according to some embodiments of the present disclosure. The semiconductor device of FIG. 18 may include and/or may be similar in many respects to the semiconductor device described above with reference to FIGS. 1 to 3, and may include additional features not mentioned above. Consequently, repeated descriptions of the semiconductor device of FIG. 18 described above with reference to FIGS. 1 to 3 may be omitted for the sake of brevity.

Referring to FIG. 18, a fourth layer 454 may be disposed between a first layer 151 and a second layer 152.

For example, a source/drain region 450 may include the first layer 151, the second layer 152, a third layer 153, and the fourth layer 454. In some embodiments, the fourth layer 454 may be disposed along the interface between the first and second layers 151 and 152. That is, the fourth layer 454 may separate the first and second layers 151 and 152. For example, the fourth layer 454 may be in contact with an uppermost surface 140a of a lower spacer 140. The fourth layer 454 may include silicon (Si)-doped with carbon (C), silicon (Si)-doped with both carbon (C) and arsenic (As), or silicon (Si)-doped with both carbon (C) phosphorus (P), or the like. However, the present disclosure is not limited thereto.

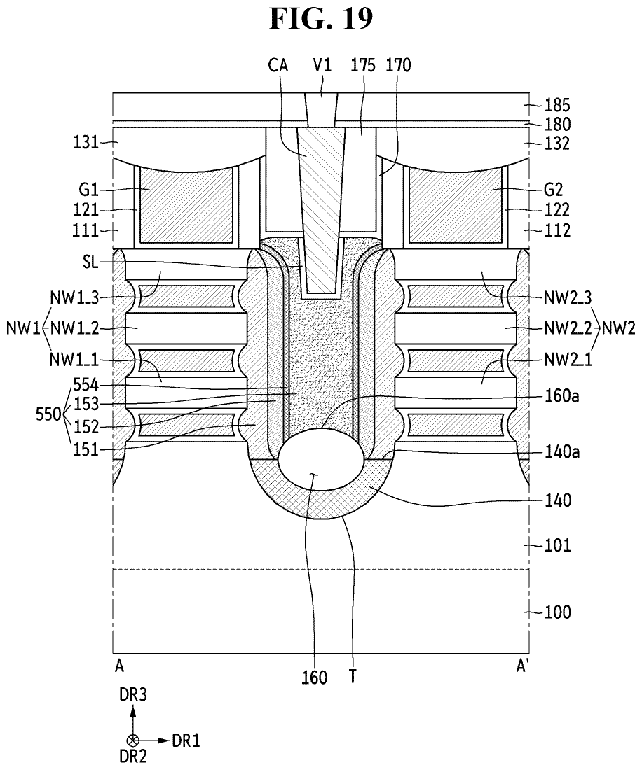

A semiconductor device, according to some embodiments of the present disclosure, is described with reference to FIG. 19, focusing on the differences from the semiconductor device depicted in FIGS. 1 to 3.

FIG. 19 is a cross-sectional view illustrating a semiconductor device according to some other embodiments of the present disclosure. The semiconductor device of FIG. 19 may include and/or may be similar in many respects to the semiconductor device described above with reference to FIGS. 1 to 3, and may include additional features not mentioned above. Consequently, repeated descriptions of the semiconductor device of FIG. 19 described above with reference to FIGS. 1 to 3 may be omitted for the sake of brevity.

Referring to FIG. 19, a fourth layer 554 may be disposed between a second layer 152 and a third layer 153.

For example, a source/drain region 550 may include a first layer 151, the second layer 152, the third layer 153, and a fourth layer 554. In some embodiments, the fourth layer 554 may be disposed along the interface between the second and third layers 152 and 153. That is, the fourth layer 554 may separate the second and third layers 152 and 153. For example, the fourth layer 554 may be exposed through a void 160. The fourth layer 554 may include silicon (Si)-doped with C, silicon (Si)-doped with both carbon (C) and arsenic (As), or silicon (Si)-doped with both carbon (C) phosphorus (P), or the like. However, the present disclosure is not limited thereto.

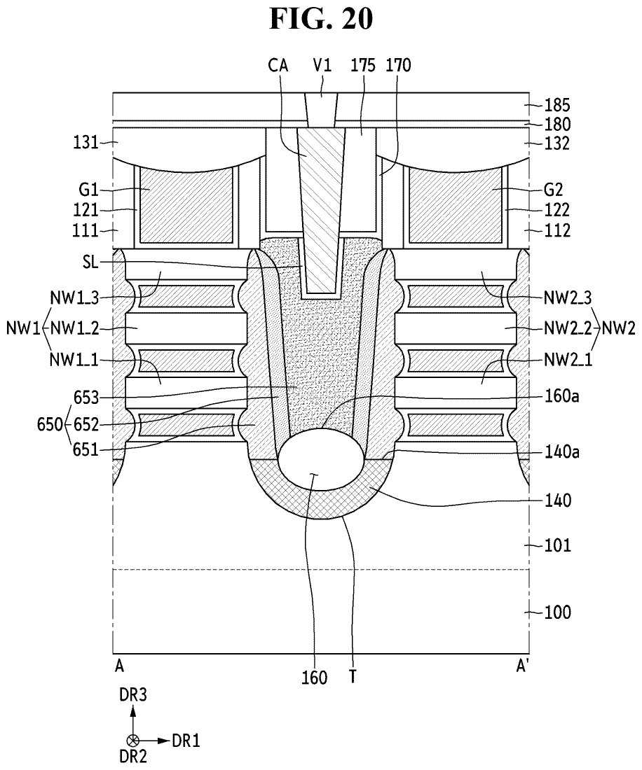

A semiconductor device, according to some embodiments of the present disclosure, is described with reference to FIG. 20, focusing on the differences from the semiconductor device depicted in FIGS. 1 to 3.

FIG. 20 is a cross-sectional view illustrating a semiconductor device, according to some other embodiments of the present disclosure. The semiconductor device of FIG. 20 may include and/or may be similar in many respects to the semiconductor device described above with reference to FIGS. 1 to 3, and may include additional features not mentioned above. Consequently, repeated descriptions of the semiconductor device of FIG. 20 described above with reference to FIGS. 1 to 3 may be omitted for the sake of brevity.

Referring to FIG. 20, the sidewalls, in the first horizontal direction DR1, of second and third layers 652 and 653 may have an inclined profile.

For example, the pitch, in the first horizontal direction DR1, between the sidewalls of a first nanosheet NW1_1 and a second layer 652 may be greater than the pitch, in the first horizontal direction DR1, between the sidewalls of a second nanosheet NW1_2 and the second layer 652. Alternatively or additionally, the pitch, in the first horizontal direction DR1, between the sidewalls of the second nanosheet NW1_2 and the second layer 652 may be greater than the pitch, in the first horizontal direction DR1, between the sidewalls of a third nanosheet NW1_3 and the second layer 652.

As another example, the pitch, in the first horizontal direction DR1, between the sidewalls of a fourth nanosheet NW2_1 and the second layer 652 may be greater than the pitch, in the first horizontal direction DR1, between the sidewalls of a fifth nanosheet NW2_2 and the second layer 652. Alternatively or additionally, the pitch, in the first horizontal direction DR1, between the sidewalls of the fifth nanosheet NW2_2 and the second layer 652 may be greater than the pitch, in the first horizontal direction DR1, between the sidewalls of a sixth nanosheet NW2_3 and the second layer 652

In some embodiments, the thickness, in the first horizontal direction DR1, of a first layer 651 being in contact with the sidewalls of the first nanosheet NW1_1 may be greater than the thickness, in the first horizontal direction DR1, of the first layer 651 being in contact with the sidewalls of the second nanosheet NW1_2. Alternatively or additionally, the thickness, in the first horizontal direction DR1, of the first layer 651 being in contact with the sidewalls of the second nanosheet NW1_2 may be greater than the thickness, in the first horizontal direction DR1, of the first layer 651 being in contact with the sidewalls of the third nanosheet NW1_3.

As another example, the thickness, in the first horizontal direction DR1, of the first layer 651 being in contact with the sidewalls of the fourth nanosheet NW2_1 may be greater than the thickness, in the first horizontal direction DR1, of the first layer 651 being in contact with the sidewalls of the fifth nanosheet NW2_2. Alternatively or additionally, the thickness, in the first horizontal direction DR1, of the first layer 651 being in contact with the sidewalls of the fifth nanosheet NW2_2 may be greater than the thickness, in the first horizontal direction DR1, of the first layer 651 being in contact with the sidewalls of the sixth nanosheet NW2_3.

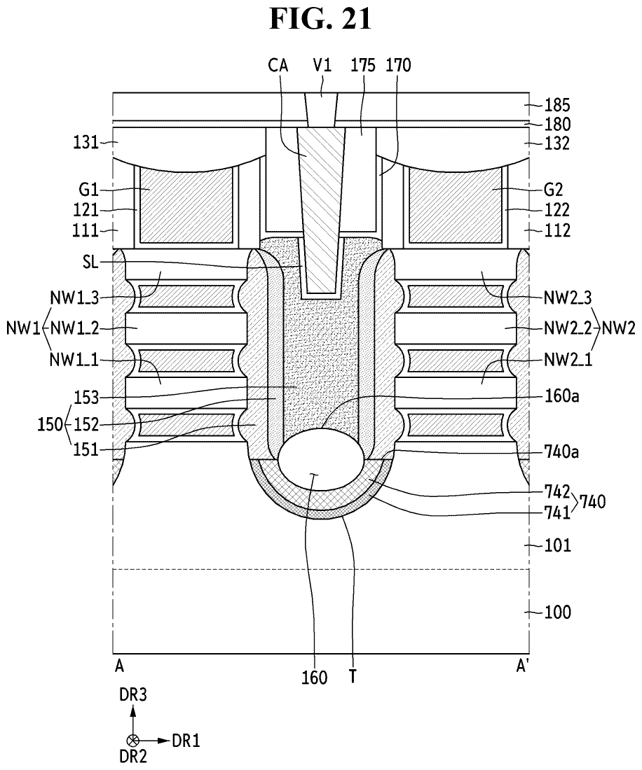

A semiconductor device, according to some embodiments of the present disclosure, is described with reference to FIG. 21, focusing on the differences from the semiconductor device depicted in FIGS. 1 to 3.

FIG. 21 is a cross-sectional view illustrating a semiconductor device, according to some other embodiments of the present disclosure. The semiconductor device of FIG. 21 may include and/or may be similar in many respects to the semiconductor device described above with reference to FIGS. 1 to 3, and may include additional features not mentioned above. Consequently, repeated descriptions of the semiconductor device of FIG. 21 described above with reference to FIGS. 1 to 3 may be omitted for the sake of brevity.

Referring to FIG. 21, a lower spacer 740 may be formed as a double layer.

For example, the lower spacer 740 may include a first lower spacer 741 and a second lower spacer 742. In some embodiments, the first lower spacer 741 may be disposed along the bottom surface of a trench T. For example, the first lower spacer 741 may be arranged in a liner shape. As shown in FIG. 21, in a cross-sectional view, taken along the first horizontal direction DR1, the first lower spacer 741 may have a semi-circular shape. The second lower spacer 742 may be disposed between the first lower spacer 741 and a void 160. The second lower spacer 742 may be exposed through the void 160. For example, the second lower spacer 742 may be arranged in a liner shape. As shown in FIG. 21, in the cross-sectional view, taken along the first horizontal direction DR1, the second lower spacer 742 may have a semi-circular shape.

In some embodiments, uppermost surfaces 740a of the first and second lower spacers 741 and 742 may be formed on a substantially similar and/or the same plane. For example, the uppermost surfaces 740a of the first and second lower spacers 741 and 742 may be in contact with a first layer 151. Each of the first and second lower spacers 741 and 742 may include an insulating material. For example, the first and second lower spacers 741 and 742 may include different materials. As another example, the first and second lower spacers 741 and 742 may include silicon nitride (SiN), silicon oxynitride (SiON), silicon oxide (SiO₂), silicon carbonitride (SiCN), silicon oxycarbonitride (SiOCN), silicon boron nitride (SiBN), silicon oxyboron nitride (SiOBN), silicon boron carbide (SiBC), silicon boron carbonitride (SiBCN), silicon oxycarbide (SiOC), a combination thereof, or the like. However, the present disclosure is not limited thereto.

Although embodiments according to the technical concept of the present disclosure have been described with reference to the accompanying drawings, the present disclosure is not limited to these embodiments and may be manufactured in various different forms. Those skilled in the art are to understand that the technical concept and essential features of the present disclosure may be implemented in other specific forms without altering them. Therefore, the embodiments described above are to be understood as illustrative and not restrictive in every respect.

What is claimed is:

1. A semiconductor device, comprising:
a substrate;
an active pattern extending in a first horizontal direction on the substrate;
at least one first nanosheet stacked on the active pattern and spaced apart from one another in a vertical direction;
at least one second nanosheet stacked on the active pattern and spaced apart from one another in the vertical direction, the at least one second nanosheet being spaced apart from the at least one first nanosheet in the first horizontal direction;
a trench formed on the active pattern between the at least one first nanosheet and the at least one second nanosheet, the trench extending into the active pattern;
a lower spacer disposed along a bottom surface of the trench, an uppermost surface of the lower spacer being formed at a first level that is lower than a second level of an uppermost surface of the active pattern;
a source/drain region on the lower spacer within the trench; and
a void formed within the trench between the lower spacer and the source/drain region, an uppermost surface of the void being formed at a third level that is higher than the second level of the uppermost surface of the active pattern.

2. The semiconductor device of claim 1, wherein the source/drain region comprises:
a first layer in contact with sidewalls of each of the at least one first nanosheet and the at least one second nanosheet in the first horizontal direction and the uppermost surface of the lower spacer;
a second layer on the first layer, at least a portion of the second layer being exposed through the void, and
a third layer on the second layer, at least a portion of the third layer being exposed through the void.

3. The semiconductor device of claim 2, wherein the source/drain region further comprises a fourth layer disposed between the first layer and the second layer.

4. The semiconductor device of claim 2, wherein the source/drain region further comprises a fourth layer disposed between the second layer and the third layer.

5. The semiconductor device of claim 1, further comprising:
a gate electrode on the active pattern and extending in a second horizontal direction different from the first horizontal direction, the gate electrode at least partially surrounding the at least one first nanosheet; and
a gate insulating layer disposed between the gate electrode and the source/drain region, the gate insulating layer being in contact with the source/drain region.

6. The semiconductor device of claim 5, wherein sidewalls of the gate insulating layer in the first horizontal direction in contact with the source/drain region are aligned with sidewalls of the at least one first nanosheet in the first horizontal direction.

7. The semiconductor device of claim 1, wherein at least a portion of the source/drain region is in contact with the active pattern on the uppermost surface of the lower spacer.

8. The semiconductor device of claim 1, wherein the at least one first nanosheet comprises a plurality of first nanosheets, and
wherein the third level of the uppermost surface of the void is lower than a fourth level of a lower surface of a lowermost nanosheet of the plurality of first nanosheets.

9. The semiconductor device of claim 1, wherein a lowermost surface of the void is formed at a fourth level that is lower than the first level of the uppermost surface of the lower spacer.

10. The semiconductor device of claim 1, wherein an upper surface of the void is formed convexly toward the source/drain region.

11. The semiconductor device of claim 1, wherein the at least one first nanosheet comprises a plurality of first nanosheets, and
wherein at least a portion of the source/drain region is between adjacent nanosheets of the plurality of first nanosheets.

12. The semiconductor device of claim 1, wherein the lower spacer comprises:
a first lower spacer in contact with the active pattern, and
a second lower spacer between the first lower spacer and the void, the second lower spacer comprising a different material from a material of the first lower spacer.

13. A semiconductor device, comprising:
a substrate;
an active pattern on the substrate and extending in a first horizontal direction on the substrate;
a first gate electrode extending in a second horizontal direction different from the first horizontal direction on the active pattern;
a second gate electrode extending in the second horizontal direction on the active pattern, the second gate electrode being spaced apart from the first gate electrode in the first horizontal direction;
a gate insulating layer disposed on sidewalls of the first gate electrode in the first horizontal direction;
a trench formed on the active pattern between the first gate electrode and the second gate electrode, the trench extending into the active pattern;
a lower spacer disposed along a bottom surface of the trench, an uppermost surface of the lower spacer being formed at a first level that is lower than a second level of an uppermost surface of the active pattern;
a source/drain region on the lower spacer within the trench; and
a void formed within the trench between the lower spacer and the source/drain region, an uppermost surface of the void being formed at a third level that is higher than the second level of the uppermost surface of the active pattern,
wherein the source/drain region comprises:
a first layer in contact with sidewalls of the gate insulating layer in the first horizontal direction and the uppermost surface of the lower spacer;
a second layer on the first layer, at least a portion of the second layer being exposed through the void; and
a third layer on the second layer, at least a portion of the third layer being exposed through the void.

14. The semiconductor device of claim 13, wherein the third layer is not in contact with the lower spacer.

15. The semiconductor device of claim 13, wherein a ratio of a volume of the void to a combined volume of the void and the source/drain region ranges from 2% to 5%.

16. The semiconductor device of claim 13, wherein a lowermost surface of the void is formed at a fourth level that is lower than the first level of the uppermost surface of the lower spacer.

17. The semiconductor device of claim 13, further comprising:
a first plurality of nanosheets stacked on the active pattern and spaced apart from one another in a vertical direction, the first plurality of nanosheets being at least partially surrounded by the first gate electrode, the first plurality of nanosheets being in contact with the first layer; and
a second plurality of nanosheets stacked on the active pattern and spaced apart from one another in the vertical direction, the second plurality of nanosheets being at least partially surrounded by the second gate electrode, the second plurality of nanosheets being spaced apart from the first plurality of nanosheets in the first horizontal direction, the second plurality of nanosheets being in contact with the first layer.

18. The semiconductor device of claim 17, wherein the first plurality of nanosheets comprises a first nanosheet disposed on an upper surface of the active pattern and a second nanosheet disposed on an upper surface of the first nanosheet, and
wherein a first pitch in the first horizontal direction between sidewalls of the first nanosheet in the first horizontal direction and the second layer is greater than a second pitch in the first horizontal direction between sidewalls of the second nanosheet in the first horizontal direction and the second layer.

19. The semiconductor device of claim 13, wherein at least a portion of the void at least partially overlaps with the uppermost surface of the lower spacer in a vertical direction.

20. A semiconductor device, comprising:
a substrate;
an active pattern on the substrate and extending in a first horizontal direction;
a first plurality of nanosheets stacked on the active pattern and spaced apart from one another in a vertical direction;
a second plurality of nanosheets stacked on the active pattern and spaced apart from one another in the vertical direction, the second plurality of nanosheets being spaced apart from the first plurality of nanosheets in the first horizontal direction;
a first gate electrode on the active pattern and extending in a second horizontal direction different from the first horizontal direction, the first gate electrode at least partially surrounding the first plurality of nanosheets;
a second gate electrode on the active pattern and extending in the second horizontal direction, the second gate electrode being spaced apart from the first gate electrode in the first horizontal direction, the second gate electrode at least partially surrounding the second plurality of nanosheets;
a first gate insulating layer disposed on sidewalls of the first gate electrode in the first horizontal direction;
a second gate insulating layer disposed on sidewalls of the second gate electrode in the first horizontal direction;
a trench formed on the active pattern between the first plurality of nanosheets and the second plurality of nanosheets, the trench extending into the active pattern;
a lower spacer disposed along a bottom surface of the trench, an uppermost surface of the lower spacer being formed at a first level that is lower than a second level of an uppermost surface of the active pattern;
a source/drain region on the lower spacer within the trench; and
a void formed within the trench between the lower spacer and the source/drain region, an uppermost surface of the void being formed at a third level that is higher than the second level of the uppermost surface of the active pattern, a lowermost surface of the void being formed at a fourth level that is lower than the first level of the uppermost surface of the lower spacer, an upper surface of the void being formed convexly toward the source/drain region,
wherein the source/drain region comprises:
a first layer in contact with sidewalls of each of the first gate insulating layer and the second gate insulating layer in the first horizontal direction and the uppermost surface of the lower spacer;
a second layer on the first layer, at least a portion of the second layer being exposed through the void; and
a third layer on the second layer, at least a portion of the third layer being exposed through the void.
